(19) United States
(12) Patent Application Publication
(10) Pub. No.: US 2011/0305848 A1
(43) Pub. Date: Dec. 15, 2011

(54) Positive photosensitive resin composition for slit coating and using said composition for forming a pattern

(75) Inventors: Chun-An Shih, Taichung (TW); Kai Min Chen, Tainan (TW)

(73) Assignee: CHI-MEI CORPORATION

(21) Appl. No.: 13/067,494

(22) Filed: Jun. 6, 2011

(30) Foreign Application Priority Data
Jun. 15, 2010 (TW) 099119601

(51) Int. Cl. G02F 1/1333; G03F 7/20; B32B 3/10; G03F 7/004

(52) U.S. Cl. 428/1.6; 430/281.1; 430/326; 428/195.1

(57) ABSTRACT

The present invention relates to a positive photosensitive resin composition and a method for forming a pattern using said composition by the slit coating process, and more particularly, to a positive photosensitive resin composition, which exhibiting excellent coating uniformity, high sensitivity, excellent developing properties and high film residual ratio and a method for forming a pattern using said composition by the slit coating process. The said composition comprises a novolac resin (A), an o-naphthaquinone diazide sulfonic acid ester (B) and a solvent (C). Wherein the novolac resin (A) has a cumulative weight percentage of from 5% to 45% with molecular weight of from 1,000 to 3,000 and the novolac resin (A) of the present invention also has a cumulative weight percentage of less than 10% with molecular weight of more than 30,000, both of which can be calculated by integral molecular weight distribution curve obtained by plotting the cumulative weight percentage versus molecular weight falling within a range between 200 and 120,000 determined by gel permeation chromatography.

### BACKGROUND OF THE INVENTION

(a) Field of the Invention

The present invention relates to a positive photosensitive resin composition and a method for forming a pattern using said composition by the slit coating process, and more particularly, to a positive photosensitive resin composition, which exhibiting excellent coating uniformity, high sensitivity, excellent developing properties and high film residual ratio and a method for forming a pattern using said composition by the slit coating process for use in semiconductor integrated circuit components of very large scale integrated circuits (hereafter referred to as VLSI) and in the manufacture of liquid crystal display elements for thin film transistors (hereafter referred to as TFT).

(b) Description of the Prior Art

The manufacture of liquid-crystal displays involves thin film transistors (TFT) and color filters, and there has been an inevitable tendency toward the large-sized of substrates. The evolution of the sizes of the substrates includes 320 nm×400 nm (first generation), 370 nm×470 nm (second generation), 550 nm×650 nm (third generation), and 680 nm×880 nm-730 nm×920 nm (fourth generation), and the objective is just to reduce production costs. In the future, as the fifth or further generation, the substrate having at least one side of longer than 1000 nm will be applied, such as, 960 nm×1100 nm, 1100 nm×1250 nm, 1100 nm×1300 nm, 1500 nm×1800 nm and 1800 nm×2000 nm, etc. The productivity can be higher compared with the fourth generation.

For a substrate having a size of 550 nm×650 nm or lesser, positive photosensitive resin for TFT circuit or Cr black matrix coated on a substrate by applying a spin coating process to form a coating results in a tendency of increasing thickness toward the peripheral portion of the substrate relative to the central portion. Moreover, the utilization rate of the raw material for spin coating is extremely low, and more than approximately 90% of the photosensitive resin material is spun away from the substrate. In other words, applying the spin coating process easily results in wastage of the positive photosensitive resin material, and reduction in productivity.

For the substrate of 730 nm×920 nm, the slit-spin coating process is applied to save the quantity of the photosensitive resin composition. In such process, the photosensitive resin composition is first coated onto the substrate by slit coating, and then the substrate is spun so that the photosensitive resin material can be uniformly spread thereon. Accordingly, utilization ratio of the photosensitive resin composition can be promoted from less than 10% to about 20%. However, the problem of edge beads still exists. For this reason, a cleaning process must be disposed to remove the edge beads on the substrate. Hence, there is an increase in investment cost of equipment and material cost of cleaning solution, which affects overall productivity.

As for the substrate having at least one side of longer than 1000 nm, only the slit coating process (that is, the spinless coating process) is applied, so that the photosensitive resin material can be more efficiently utilized.

For example, related technologies are referred to “Display (Japanese Journal), November 2002, page 36, Technology and Apparatus for Manufacturing Large-Sized Substrates of Color Filters of the Fifth Generation with the Slit Coating Process” and “Electric Material (Japanese Journal), June 2002, page 107, Manufacturing of Substrates for Planar Displays with the Slit Coating Process”. Adopting the aforementioned slit coating process without the spinning step, utilization ratio of the photosensitive resin material is approximately 100% and the problem of edge beads no longer exists. Therefore the cost for materials, equipments and cleaning solution can be greatly lowered.

However, adopting the slit coating process causes the problem of poor coating uniformity extremely easily. Particularly, in recent years, as the display area of image display equipments increases, such as televisions and computer monitors, it becomes difficult for the slit coating method to ensure picture quality uniformity of large-sized displays.

A Japanese Patent Publication No. 2004-258099 discloses the use of a positive photosensitive resin composition comprising two types of novolac resin with different weight average molecular weight and a naphthaquinone diazide compound, which is able to form good patterns on a substrate. However, applying slit coating process to coat the composition onto a substrate still causes the problems of poor coating uniformity, poor developing properties and low film residual ratio, and thus cannot be accepted by the industry.

### SUMMARY OF THE INVENTION

The primary objective of the present invention lies in providing a positive photosensitive resin composition and a method for forming a pattern using said composition by the slit coating process, and more particularly, a positive photosensitive resin composition, which exhibiting excellent coating uniformity, high sensitivity, excellent developing properties and high film residual ratio and a method for forming a pattern using said composition by the slit coating process.

### BRIEF DESCRIPTION OF THE DRAWINGS

FIG. 1 shows a cross-sectional view illustrating a TFT substrate for LCD;

FIG. 2 shows an integral molecular weight distribution curve of the novolac resin (A) according to the present invention taking the molecular weight on the horizontal axis, and the cumulative weight percentage on the vertical axis; and

FIG. 3 shows a schematic view illustrating the distribution of film thickness measurement points of the pre-baked coating film of the photosensitive resin composition formed on a substrate.

### BRIEF DESCRIPTION OF THE TABLES

Table 1 shows the formulations of Synthesis Example of the novolac resin (A) according to the present invention;

Table 2 shows the molecular weight distribution of Synthesis Examples of the novolac resin (A), which include the weight percentage of novolac resin with molecular weight of from 1,000 to 3,000 and molecular weight of more than 30,000 in the novolac resin (A);

Table 3 shows the formulations and the evaluation results of Examples and Comparative Examples according to the present invention;

### DETAILED DESCRIPTION OF THE PREFERRED EMBODIMENTS AND EXAMPLES

The positive photosensitive resin composition of the present invention comprises a novolac resin (A), an o-naphthaquinone diazide sulfonic acid ester (B) and a solvent (C), wherein the novolac resin (A) has a cumulative weight percentage of from 5% to 45% with molecular weight of from 1,000 to 3,000 and the novolac resin (A) of the present invention also has a cumulative weight percentage of less than 10% with molecular weight of more than 30,000, both of which can be calculated by integral molecular weight distribution curve obtained by plotting the cumulative weight percentage versus molecular weight falling within a range between 200 and 120,000 determined by gel permeation chromatography.

The present invention relates to a method for forming a pattern using the positive photosensitive resin composition of the present invention comprising the procedures of pre-baking, exposure, developing and post-baking the positive photosensitive resin composition sequentially, thereby forming the pattern.

The present invention relates to a thin-film transistor array substrate including a pattern, wherein the pattern is formed by using the method described to form a pattern.

The present invention relates to a liquid crystal display element including the thin film transistor array substrate aforementioned.

The following gives a detailed description of each component of the present invention:

### Positive Photosensitive Resin Components:

### Novolac Resin (A)

The novolac resin (A) of the present invention can be generally obtained by subjecting an aromatic hydroxy compound and an aldehyde to condensation in the presence of an acid catalyst. Examples of the aromatic hydroxy compound include: phenol; cresols such as m-cresol, p-cresol, o-cresol, and the like; xylenols such as 2,3-xylenol, 2,5-xylenol, 3,5-xylenol, 3,4-xylenol, and the like; alkyl phenols such as m-ethyl phenol, p-ethyl phenol, o-ethyl phenol, 2,3,5-trimethyl phenol, 2,3,5-triethyl phenol, 4-tert-butyl phenol, 3-tert-butyl phenol, 2-tert-butyl phenol, 2-tert-butyl-4-methyl phenol, 2-tert-butyl-5-methyl phenol, 6-tert-butyl-3-methyl phenol, and the like; alkoxy phenols such as p-methoxy phenol, m-methoxy phenol, p-ethoxy phenol, m-ethoxy phenol, p-propoxy phenol, m-propoxy phenol, and the like; isopropenyl phenols such as o-isopropenyl phenol, p-isopropenyl phenol, 2-methyl-4-isopropenyl phenol, 2-ethyl-4-isopropenyl phenol, and like; aryl phenols such as phenyl phenol; polyhydroxyphenols such as 4,4′-dihydroxy biphenyl, bisphenol A, m-resorcinol, p-hydroquinone, 1,2,3-pyrogallol, and the like. These aforementioned compounds may be used alone or as a mixture of two or more. Among these, o-cresol, m-cresol, p-cresol, 2,5-xylenol, 3,5-xylenol and 2,3,5-trimethyl phenol may be preferred.

Examples of the aldehyde which may be used in the condensation reaction with the aromatic hydroxy compound include: formaldehyde, paraformaldehyde, trioxane, acetaldehyde, propylaldehyde, butyric aldehyde, trimethylacetaldehyde, acrolein, crotonaldehyde, cyclo hexanealdehyde, furfural, furylacrolein, benzaldehyde, terephthal aldehyde, phenylacetaldehyde, α-phenyl propylaldehyde, β-phenyl propylaldehyde, o-hydroxy benzaldehyde, m-hydroxy benzaldehyde, p-hydroxy benzaldehyde, o-methyl benzaldehyde, m-methyl benzaldehyde, p-methyl benzaldehyde, o-chloro benzaldehyde, m-chloro benzaldehyde, p-chloro benzaldehyde, cinnamic aldehyde, and the like. These aforementioned aldehydes may be used alone or as a mixture of two or more. Among these, formaldehyde may be preferred.

Examples of the acid catalyst which may be used in the condensation reaction include: hydrochloric acid, sulfuric acid, formic acid, acetic acid, oxalic acid, p-toluenesulfonic acid, and the like.

The novolac resin (A) of the present invention has a cumulative weight percentage of from 5% to 45%, preferably from 10% to 40%, and more preferably from 15% to 35% with molecular weight of from 1,000 to 3,000, and the novolac resin (A) of the present invention also has a cumulative weight percentage of less than 10%, preferably less than 8%, and more preferably less than 6% with molecular weight of more than 30,000, both of which are calculated by integral molecular weight distribution curve obtained by plotting the cumulative weight percentage versus molecular weight falling within a range between 200 and 120,000 determined by gel permeation chromatography.

When the cumulative weight percentage of the novolac resin (A) with molecular weight of from 1,000 to 3,000 is less than 5%, or the cumulative weight percentage of the novolac resin (A) with molecular weight of more than 30,000 exceeds 10%, coating uniformity reduces excessively by a slit coating process using the obtained positive photosensitive resin composition, moreover, sensitivity and developing properties may be deteriorated. Whereas, the cumulative weight percentage of the novolac resin (A) with molecular of from 1,000 to 3,000 exceeding 45% is not preferred because the film residual ratio may be significantly lowered.

The aforementioned novolac resin (A) may be used alone or in combination of two or more.

o-Naphthoquinone Diazide Sulfonic Acid Ester (B)

The photosensitive material used in the present invention can be o-naphthaquinone diazide sulfonic acid ester (B), which is not particular limited and one regularly used is preferable. An ester of an o-naphthaquinone diazide sulfonic acid with a hydroxy compound is preferred, and an ester of an o-naphthaquinone diazide sulfonic acid with a polyhydroxy compound is more preferred. Furthermore, the aforementioned esters can be fully esterified or partially esterified. Examples of the o-naphthaquinone diazide sulfonic acid include: o-naphthaquinone diazide-4-sulfonic acid, o-naphthaquinone diazide-5-sulfonic acid, o-naphthaquinone diazide-6-sulfonic acid, and the like. Types of the hydroxy compounds are represented as follows:

(1) Hydroxy benzophenones, examples of which include: 2,3,4-trihydroxy benzophenone, 2,4,4′-trihydroxy benzophenone, 2,4,6-trihydroxy benzophenone, 2,3,4,4′-tetrahydroxy benzophenone, 2,2′,4,4′-tetrahydroxy benzophenone, 2,3′,4,4′,6-pentahydroxy benzophenone, 2,2′,3,4,4′-pentahydroxy benzophenone, 2,2′,3,4,5′-pentahydroxy benzophenone, 2,3′,4,5,5′-pentahydroxy benzophenone, 2,3,3′,4,4′,5′-hexahydroxy benzophenones, and the like.

(2) Hydroxy aryl compounds represented by the following Formula (I):

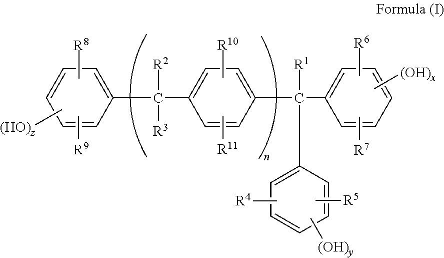

wherein each of R¹ to R³ is independently a hydrogen atom or a lower alkyl group; each of R⁴ to R⁹ is independently a hydrogen atom, a halogen atom, a lower alkyl group, a lower alkoxy group, a lower alkenyl group or a cycloalkyl group; each of R¹⁰ to R¹¹ is independently a hydrogen atom, a halogen atom or a lower alkyl group; each of x, y and z independently denotes an integer from 1 to 3 and n denotes 0 or 1. Examples of hydroxy aryl compounds represented by the Formula (I) include: tri(4-hydroxyphenyl) methane, bis(4-hydroxy-3,5-dimethylphenyl)-4-hydroxyphenyl methane, bis(4-hydroxy-3,5-dimethylphenyl)-3-hydroxyphenyl methane, bis(4-hydroxy-3,5-dimethylphenyl)-2-hydroxyphenyl methane, bis(4-hydroxy-2,5-dimethylphenyl)-4-hydroxyphenyl methane, bis(4-hydroxy-2,5-dimethylphenyl)-3-hydroxyphenyl methane, bis(4-hydroxy-2,5-dimethylphenyl)-2-hydroxyphenyl methane, bis(4-hydroxy-3,5-dimethylphenyl)-3,4-dihydroxyphenyl methane, bis(4-hydroxy-2,5-dimethylphenyl)-3,4-dihydroxyphenyl methane, bis(4-hydroxy-3,5-dimethylphenyl)-2,4-dihydroxyphenyl methane, bis(4-hydroxy-2,5-dimethylphenyl)-2,4-dihydroxyphenyl methane, bis(4-hydroxyphenyl)-3-methoxy-4-hydroxyphenyl methane, bis(3-cyclohexyl-4-hydroxyphenyl)-3-hydroxyphenyl methane, bis(3-cyclohexyl-4-hydroxyphenyl)-2-hydroxyphenyl methane, bis(3-cyclohexyl-4-hydroxyphenyl)-4-hydroxyphenyl methane, bis(3-cyclohexyl-4-hydroxy-6-aryl methyl)-2-hydroxyphenyl methane, bis(3-cyclohexyl-4-hydroxy-6-methylphenyl)-3-hydroxyphenyl methane, bis(3-cyclohexyl-4-hydroxy-6-methylphenyl)-4-hydroxyphenyl methane, bis(3-cyclohexyl-4-hydroxy-6-methylphenyl)-3,4-dihydroxyphenyl methane, bis(3-cyclohexyl-6-hydroxyphenyl)-3-hydroxyphenyl methane, bis(3-cyclohexyl-6-hydroxyphenyl)-4-hydroxyphenyl methane, bis(3-cyclohexyl-6-hydroxyphenyl)-2-hydroxyphenyl methane, bis(3-cyclohexyl-6-hydroxy-4-methylphenyl)-2-hydroxyphenyl methane, bis(3-cyclohexyl-6-hydroxy-4-methylphenyl)-4-hydroxyphenyl methane, bis(3-cyclohexyl-6-hydroxy-4-methylphenyl)-3,4-dihydroxyphenyl methane, 1-[1-(4-hydroxyphenyl)isopropyl]-4-[1,1-bis(4-hydroxyphenyl)ethyl] benzene, 1-[1-(3-methyl-4-hydroxyphenyl)isopropyl]-4-[1,1-bis(3-methyl-4-hydroxyphenyl)ethyl] benzene, and the like.

(3) (Hydroxyphenyl)hydrocarbon compounds represented by the following Formula (II):

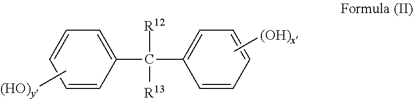

wherein each of R¹² and R¹³ is independently a hydrogen atom or a lower alkyl group; each of x′ and y′ independently denotes an integer from 1 to 3. Examples of (hydroxyphenyl)hydrocarbon compounds represented by the Formula (II) include: 2-(2,3,4-trihydroxyphenyl)-2-(2′,3′,4′-trihydroxyphenyl) propane, 2-(2,4-dihydroxyphenyl)-2-(2′,4′-dihydroxyphenyl) propane, 2-(4-hydroxyphenyl)-2-(4′-hydroxyphenyl) propane, bis(2,3,4-trihydroxyphenyl) methane, bis(2,4-dihydroxyphenyl) methane, and the like.

(4) Other aromatic hydroxy compounds, examples of which include: phenol, p-methoxyphenol, dimethyl phenol, hydroquinone, bisphenol A, naphthol, pyrocatechol, pyrogallol monomethyl ether, pyrogallol-1,3-dimethyl ether, gallic acid, partial esterified or partial etherified gallic acid, and the like.

These aforementioned hydroxy compounds may be used alone or as a mixture of two or more. Among these, 2,3,4-trihydroxy benzophenone, 2,3,4,4′-tetrahydroxy benzophenone may be preferred.

The o-naphthoquinone diazide sulfonic acid ester (B) used as the photosensitive material in the present invention can be produced by condensation of a quinone diazide group-containing compound such as o-naphthaquinone diazide-4 (or 5) sulfonic acid halide and the aforementioned hydroxy compounds represented from (1) to (4) in an organic solvent such as dioxane, N-pyrrolidone or acetamide, in the presence of alkali such as triethanolamine, carbonic acid alkali or hydrogen carbonate alkali, followed by fully esterification or partial esterification.

The ester can be produced by condensation of a o-naphthaquinone diazide-4 (or 5) sulfonic acid halide and a hydroxy compound with more than 50% by mole, and preferably more than 60% by mole per 100% by mole of the total hydroxyl group in the hydroxy compound, i.e. the esterification rate is higher than 50%, preferably higher than 60%.

The amount of the o-naphthoquinone diazide sulfonic acid ester (B) of the present invention is generally 1 to 100 parts by weight, preferably 10 to 50 parts by weight, and more preferably 20 to 40 parts by weight, based on 100 parts by weight of the novolac resin (A).

### Solvent (C)

An organic solvent which exhibits favorable miscibility with other organic components may be used as the solvent (C) of the present invention.

Examples of the solvent (C) used in the present invention include: (poly)alkylene glycol monoalkyl ethers such as ethylene glycol monomethyl ether, ethylene glycol monoethyl ether, diethylene glycol monoethyl ether, diethylene glycol mono-n-propyl ether, diethylene glycol mono-n-butyl ether, triethylene glycol monomethyl ether, triethylene glycol monoethyl ethers, propylene glycol monomethyl ether, propylene glycol monoethyl ether, dipropylene glycol monomethyl ether, dipropylene glycol monoethyl ether, dipropylene glycol mono-n-propyl ether, dipropylene glycol mono-n-butyl ether, tripropylene glycol monomethyl ether, tripropylene glycol monoethyl ether, and the like; (poly)alkylene glycol monoalkyl ether acetates such as ethylene glycol monomethyl ether acetate, ethylene glycol monoethyl ether acetate, propylene glycol monomethyl ether acetate, propylene glycol monoethyl ether acetate, and the like; other ethers such as diethylene glycol dimethyl ether, diethylene glycol methylethyl ether, diethylene glycol diethyl ether, tetrahydrofuran, and the like; ketones such as methylethyl ketone, cyclohexanone, 2-heptanone, 3-heptanone, and the like; alkyl lactates such as methyl lactate, ethyl lactate, and the like; other esters such as methyl 2-hydroxypropionate, ethyl 2-hydroxypropionate, methyl 3-methoxypropionate, ethyl 3-methoxypropionate, methyl 3-ethoxypropionate, ethyl 3-ethoxypropionate, ethyl ethoxyacetate, ethyl hydroxyacetate, methyl 2-hydroxy-3-methylbutanoate, 3-methyl-3-methoxybutyl acetate, 3-methyl-3-methoxybutyl propionate, ethyl acetate, n-propyl acetate, isopropyl acetate, n-butyl acetate, isobutyl acetate, n-amyl acetate, isoamyl acetate, n-butyl propionate, ethyl butyrate, n-propyl butyrate, isopropyl butyrate, n-butyl butyrate, methyl pyruvate, ethyl pyruvate, n-propyl pyruvate, methyl acetoacetate, ethyl acetoacetate, ethyl 2-oxybutyrate, and the like; aromatic hydrocarbons such as toluene, xylene, and the like; carboxylic amides such as N-methylpyrrolidone, N,N-dimethylformamide, N,N-dimethylethanamide, and the like. The aforementioned solvents may be used alone or as a mixture of two or more. Among these, propylene glycol monomethyl ether acetate and ethyl lactate may be preferred.

The amount of the solvent (C) of the present invention is generally 700 to 2,000 parts by weight, preferably 800 to 1,800 parts by weight, and more preferably 900 to 1,600 parts by weight, based on 100 parts by weight of the novolac resin (A).

An aromatic hydroxy compound may be further added for the purpose of adjusting the sensitivity or viscosity of the composition to the positive photosensitive resin composition of the present invention. Examples of the aromatic hydroxy compounds of the present invention include: TPPA-1000P, TPPA-100-2C, TPPA-1100-3 C, TPPA-1100-4C, TPPA-1200-24X, TPPA-1200-26X, TPPA-1300-235T, TPPA-1600-3M6C, TPPA-MF (trade names, manufactured by Japan Honshu Chemical Industry), and the like. Among these, TPPA-600-3M6C and TPPA-MF may be preferred. The aforementioned aromatic hydroxy compounds may be used alone or as a mixture of two or more. The amount of the aromatic hydroxy compound is generally 0 to 20 parts by weight, preferably 0.5 to 18 parts by weight, and more preferably 1.0 to 15 parts by weight, based on 100 parts by weight of the novolac resin (A).

An adhesion auxiliary agent, a surface levering agent, a diluent and a dye having miscibility may be also added to the positive photosensitive resin composition of the present invention if necessary.

The adhesion auxiliary agent may be used in the present invention for improving adhesive properties of the positive photosensitive resin composition with the substrate includes melamine compounds and silane compounds. Examples of the melamine compounds include: Cymel-300, Cymel-303 (trade names, manufactured by Mitsui Chemicals), MW-30 MH, MW-30, MS-11, MS-001, MX-750, MX-706 (trade names, manufactured by Sanwa Chemical), and the like. Examples of the silane compounds include: vinyltrimethoxy silane, vinyltriethoxy silane, 3-(meth)acryloxypropyltrimethoxysilane, vinyltris(2-methoxyethoxyl)silane, N-(2-aminoethyl)-3-aminopropylmethyldimethoxysilane, N-(2-aminoethyl)-3-aminopropyltrimethoxysilane, 3-aminopropyltriethoxysilane, 3-glycidylpropyltrimethoxysilane, 3-glycidylpropylmethyldimethoxysilane, 2-(3,4-epoxycyclohexyl)ethyltrimethoxysilane, 3-chloropropylmethyldimethoxysilane, 3-chloropropyltrimethoxysilane, 3-methacryloxypropyltrimethoxysilane, 3-mercaptopropyltrimethoxysilane, bis-1,2-(trimethoxysilyl)ethane, and the like. The amount of the melamine compounds is generally 0 to 20 parts by weight, preferably 0.5 to 18 parts by weight, and more preferably 1.0 to 15 parts by weight, based on 100 parts by weight of the novolac resin (A); whereas the amount of the silane compounds is generally 0 to 2 parts by weight, preferably 0.001 to 1 parts by weight, and more preferably 0.005 to 0.8 parts by weight, based on 100 parts by weight of the novolac resin (A).

The surface levering agent may be used in the present invention includes fluorine type surfactants and silicone type surfactants. Examples of fluorine type surfactants include: Flourate FC-430, FC-431 (trade names, manufactured by 3M), F-top EF122A, 122B, 122C, 126, BL20 (trade names, manufactured by Tochem), and the like; whereas examples of silicone type surfactants include SF8427, SI-129PA (trade names, manufactured by Toray Dow Corning Silicone), and the like. The amount of the surfactants is generally 0 to 1.2 parts by weight, preferably 0.025 to 1.0 parts by weight, and more preferably 0.050 to 0.8 parts by weight, based on 100 parts by weight of the novolac resin (A).

Suitable diluent for the present invention includes RE801, RE802 (trade names, manufactured by Teikoku Ink), and the like.

Examples of suitable dye having miscibility for the present invention include curcumin, coumarin, azo dyes, and the like. In addition, other additives such as a plasticizer, a stabilizer, and the like may be also added to the composition of the present invention if necessary.

### Preparation of the Positive Photosensitive Resin Composition

For the preparation of the positive photosensitive resin composition according to the present invention may be formed by blending the novolac resin (A), the o-naphthoquinone diazide sulfonic acid ester (B) and the solvent (C) in a mixer to obtain a solution, and the additives such as an adhesion auxiliary agent, a surfactant, a diluent, a dye having miscibility, a plasticizer, a stabilizer, or the like can be added as needed.

### Method for Forming a Pattern Using the Positive Photosensitive Resin Composition

The method for forming a pattern using the aforementioned positive photosensitive resin composition of the present invention comprises first coating the photosensitive resin composition onto a substrate by a slit coating process, and then removing the solvent by pre-baking to form a pre-baked coating film. The pre-baking conditions may vary depending on the type of each component in the composition and the compounding ratio. Usually the conditions may involve a temperature of 70 to 110° C. for a time period of 1 to 15 minutes.

After pre-baking, the coating film is exposed to UV light through a mask having a predetermined pattern, and then developed in a developing solution at a temperature of 23±2° C. for a time period of 15 seconds to 5 minutes to dissolve and remove unwanted regions of the coating film, so as to give a desired pattern. The UV light used for this purpose can be g line, h line, I line and the like. As the UV light source, a high-pressure mercury lamp, an ultra high-pressure mercury lamp, a metal halide lamp or the like can be used.

Examples of the developing solution may be used in the present invention include alkali compounds such as: sodium hydroxide, potassium hydroxide, sodium carbonate, sodium hydrogencarbonate, potassium carbonate, potassium hydrogencarbonate, sodium silicate, sodium methylsilicate, aqueous ammonia, ethylamine, diethylamine, dimethylethanolamine, tetramethylammonium hydroxide, tetraethylammonium hydroxide, choline, pyrrole, piperidine, 1,8-diazabicyclo(5,4,0)-7-undecene, and the like.

The concentration of the developing solution is 0.001% to 10% by weight, preferably 0.005% to 5% by weight, and more preferably 0.01% to 1% by weight.

After developed with the developing solution made up from the aforementioned alkali compounds, the resulted pattern is sufficiently washed with water and then dried with compressed air or compressed nitrogen. Finally, it is post-baked with a heating device such as a hot plate at a temperature of 100 to 250° C. for a time period of 1 to 60 minutes or an oven at a temperature of 100 to 250° C. for a time period of 5 to 90 minutes.

Through the aforementioned procedures, the pattern can be obtained on the substrate.

### Thin-Film Transistor Array Substrate

The manufacturing method of the thin-film transistor array substrate (abbreviated to TFT array substrate) of the present invention can be formed according to the aforementioned method for forming a pattern, that is, coating the positive photosensitive resin composition onto a glass substrate containing a thin film formed from aluminum, chromium, silicon nitride, amorphous silicon, or the like or onto a plastic substrate by a slit coating process to form a positive photo resist layer, and then etching and stripping the photo resist after pre-baking, exposure, developing and post-baking procedures. By repeating the above procedures, a TFT array substrate having TFTs or electrodes can be obtained.

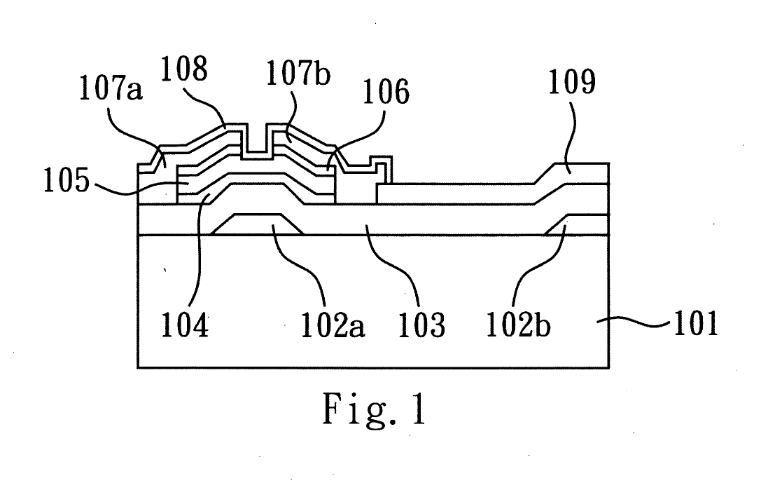

Referring to FIG. 1, hereafter, a description about a TFT array substrate for LCD is represented as follows:

FIG. 1 shows a cross-sectional view illustrating a TFT substrate for LCD. First, a gate electrode (102a) and a storage capacitor Cs electrode (102b) may be disposed on the thin film formed from aluminum or the like of a glass substrate (101). Next, a silicon oxide film (SiOx) (103), a silicon nitride film (SiNx) (104), or the like may be disposed on the gate electrode (102a) to form a dielectric film, and on this dielectric film, an amorphous silicon layer (a-Si) (105) may be formed as a semiconductor active layer. Whereupon, in order to reduce junction resistance, an amorphous silicon layer (106) doped with N⁺ impurities may be emplaced. After which, metals such as aluminum or the like may be used to form a drain electrode (107a) and a source electrode (107b). The drain electrode (107a) is connected to a data signal line, and the source electrode (107b) is connected to a pixel electrode (or sub-pixel electrode) (109). Finally, for protecting the semiconductor layer (a-Si layer), the drain electrode and the source electrode, a passivation film (108) such as silicon nitride film or the like may be placed.

### Liquid Crystal Display Element

A liquid crystal display element of the present invention including the aforementioned TFT array substrate can be formed according to the method for forming a pattern of the present invention. Moreover, other components may be also included as needed.

Examples of basic construction modes of the aforementioned liquid crystal display element are represented as follows: (1) The liquid crystal display element may be produced by first inserting spacers between the aforementioned TFT array substrate (drive substrate) of the present invention formed by arranging the drive elements such as TFT or the like and the pixel electrodes (conducting layers) and the color filter substrate fabricated from color filters and counter electrodes (conducting layers), and after aligning the two substrates oppositely, sealing liquid crystal material into the gap; or, (2) the liquid crystal display element may be produced by first inserting spacers between color filters on TFT array substrate fabricated from forming color filters directly on the aforementioned TFT array substrate of the present invention and the opposing substrate disposed with counter electrodes (conducting layers), and after aligning the two substrates oppositely, sealing liquid crystal material into the gap.

Examples of the aforementioned conducting layers include: ITO (indium tin oxide) films; metal films such as aluminum, zinc, copper, iron, nickel, chromium, molybdenum, and the like; metal oxide films such as silicon dioxide, and the like. Among these, films with transparency are preferred, and ITO films are more preferably.

Examples of the substrates used for the aforementioned TFT array substrates, color filter substrates and opposing substrates of the present invention include well-known glass such as soda-lime glass, low-expansion glass, non-alkali glass, quartz glass, and the like. Moreover, substrates fabricated from plastic films may be also used.

Hereinafter, the present invention will be further illustrated more specifically by the following examples, although the scope of the present invention is by no way limited by these examples.

### Synthesis of Novolac Resin

### Synthesis Example 1

A 1000 ml four-necked conical flask equipped which contains a stirrer, a heater, a condenser and a thermometer is purged with nitrogen. Then a mixture comprising 64.89 g (0.6 moles) of m-cresol and 43.26 g (0.4 moles) of p-cresol was charged to the flask, and 48.69 g (0.6 moles) of 37% by weight of formalin and 1.80 g (0.02 moles) of oxalic acid were added to the mixture. Thereafter, the temperature of the solution was elevated to 100° C. by slowly stirring, and polymerization was performed at this temperature for 5 hours. After elevating the temperature of the solution to 180° C., the solution was dried under reduced pressure of 10 mm Hg, followed by devolatilizing the solvent, thereby obtaining a novolac resin (A-1). The molecular weight distribution of the novolac resin (A-1) was analyzed by gel permeation chromatography, and the results were shown in Table 2.

### Synthesis Examples 2 to 4

The novolac resins (A-2) to (A-4) were prepared by repeating the procedure of Synthesis Example 1, except that the kind and dosage of the raw materials were changed. The formulation and reaction conditions were shown in Table 1. The molecular weight distribution of the novolac resins (A-2) to (A-4) were analyzed by gel permeation chromatography, and the results were shown in Table 2.

### Synthesis Example 5

A mixture of 50 parts by weight of cresol novolac resin (TO-547, manufactured by Sumitomo Bakelite) containing approximately 4.0% of phenolic dimer and 50 parts by weight of cresol novolac resin (GTR-M2, manufactured by Gun Ei Chemical) containing approximately 6.0% phenolic dimer was added to 300 parts by weight of propyleneglycol monomethylether acetate as a solvent. Thereafter, the solution was continually stirred at room temperature until completely dissolved, followed by devolatilizing the solvent, thereby obtaining a novolac resin (A-5). The molecular weight distribution of the novolac resin (A-5) was analyzed by gel permeation chromatography, and the results were shown in Table 2.

### Synthesis Example 6

100 parts by weight of the novolac resin (A-1) obtained in the above Synthesis Example 1 was added to 300 parts by weight of propylene glycol monomethyl ether acetate as a solvent. Thereafter, the solution was continually stirred at room temperature until completely dissolved. After continually stirring the solution for 30 minutes simultaneously with the addition of 100 parts by weight of acetone, the precipitate was separated by filtration, followed by devolatilizing the solvent, thereby obtaining a novolac resin (A-6). The molecular weight distribution of the novolac resin (A-6) was analyzed by gel permeation chromatography, and the results were shown in Table 2.

### Synthesis Example 7

100 parts by weight of the novolac resin (A-2) obtained in the above Synthesis Example 2 was added to 300 parts by weight of propylene glycol monomethyl ether acetate as a solvent. Thereafter, the solution was continually stirred at room temperature until completely dissolved. After continually stirring the solution for 30 minutes simultaneously with the addition of 150 parts by weight of isopropylbenzene, the precipitate was separated by filtration, followed by devolatilizing the solvent, thereby obtaining a purified novolac resin. The above-mentioned purified novolac resin was then added to 250 parts by weight of propylene glycol monomethyl ether acetate as a solvent. Thereafter, the solution was continually stirred at room temperature until completely dissolved. After continually stirring the solution for 30 minutes simultaneously with the addition of 70 parts by weight of acetone, the precipitate was separated by filtration, followed by devolatilizing the solvent, thereby obtaining a novolac resin (A-7). The molecular weight distribution of the novolac resin (A-7) was analyzed by gel permeation chromatography, and the results were shown in Table 2.

### Synthesis Example 8

100 parts by weight of the novolac resin (A-3) obtained in the above Synthesis Example 3 was added to 300 parts by weight of propylene glycol monomethyl ether acetate as a solvent. Thereafter, the solution was continually stirred at room temperature until completely dissolved. After continually stirring the solution for 30 minutes simultaneously with the addition of 150 parts by weight of acetone, the precipitate was separated by filtration, followed by devolatilizing the solvent, thereby obtaining a purified novolac resin. The above-mentioned purified novolac resin was then added to 250 parts by weight of propylene glycol monomethyl ether acetate as a solvent. Thereafter, the solution was continually stirred at room temperature until completely dissolved. After continually stirring the solution for 30 minutes simultaneously with the addition of 100 parts by weight of acetone, the precipitate was separated by filtration, followed by devolatilizing the solvent, thereby obtaining a novolac resin (A-8). The molecular weight distribution of the novolac resin (A-8) was analyzed by gel permeation chromatography, and the results were shown in Table 2.

### Synthesis Example 9

100 parts by weight of the novolac resin (A-4) obtained in the above Synthesis Example 4 was added to 300 parts by weight of propylene glycol monomethyl ether acetate as a solvent. Thereafter, the solution was continually stirred at room temperature until completely dissolved. After continually stirring the solution for 30 minutes simultaneously with the addition of 180 parts by weight of ethanol, the precipitate was separated by filtration, followed by devolatilizing the solvent, thereby obtaining a purified novolac resin. The above-mentioned purified novolac resin was then added to 250 parts by weight of propylene glycol monomethyl ether acetate as a solvent. Thereafter, the solution was continually stirred at room temperature until completely dissolved. After continually stirring the solution for 30 minutes simultaneously with the addition of 100 parts by weight of isopropylbenzene, the precipitate was separated by filtration, followed by devolatilizing the solvent, thereby obtaining a novolac resin (A-9). The molecular weight distribution of the novolac resin (A-9) was analyzed by gel permeation chromatography, and the results were shown in Table 2.

### Synthesis Example 10

100 parts by weight of the novolac resin (A-1) obtained in the above Synthesis Example 1 was added to 300 parts by weight of propylene glycol monomethyl ether acetate as a solvent. Thereafter, the solution was continually stirred at room temperature until completely dissolved. After continually stirring the solution for 30 minutes simultaneously with the addition of 100 parts by weight of ethylbenzene, the precipitate was separated by filtration, followed by devolatilizing the solvent, thereby obtaining a purified novolac resin. The above-mentioned purified novolac resin was then added to 250 parts by weight of propylene glycol monomethyl ether acetate as a solvent. Thereafter, the solution was continually stirred at room temperature until completely dissolved. After continually stirring the solution for 30 minutes simultaneously with the addition of 100 parts by weight of acetone, the precipitate was separated by filtration, followed by devolatilizing the solvent, thereby obtaining a repurified novolac resin. The above-mentioned repurified novolac resin was then added to 200 parts by weight of propylene glycol monomethyl ether acetate as a solvent. Thereafter, the solution was continually stirred at room temperature until completely dissolved. After continually stirring the solution for 30 minutes simultaneously with the addition of 80 parts by weight of isopropylbenzene, the precipitate was separated by filtration, followed by devolatilizing the solvent, thereby obtaining a novolac resin (A-10). The molecular weight distribution of the novolac resin (A-10) was analyzed by gel permeation chromatography, and the results were shown in Table 2.

### EXAMPLES AND COMPARATIVE EXAMPLES OF THE PHOTOSENSITIVE RESIN COMPOSITION

### Example 1

A mixture of 100 parts by weight of the novolac resin (A-6), 25 parts by weight of the ester of 2,3,4-trihydroxy benzophenone and 1,2-naphthaquinone diazide-5-sulfonic acid (B-1) (average esterification rate: 85%), 10 parts by weight of the ester of 2,3,4,4′-tetrahydroxy benzophenone and 1,2-naphthaquinone diazide-5-sulfonic acid (B-2) (average esterification rate: 85%) was added to 1200 parts by weight of propylene glycol monomethyl ether acetate as a solvent (C-1). Then, the mixture was shaken and stirred for blending and dissolution, and polymerization was performed for 3 hours, thereby obtaining a positive photosensitive resin composition. The positive photosensitive resin composition was evaluated with the Evaluation Method described afterwards, and the results were shown in Table 3.

### Examples 2 to 7

The procedure of Example 1 is repeated, except that the kind and dosage of the raw materials were changed. The formulation and evaluation results were shown in Table 3.

### Comparative Examples 1 to 5

The procedure of Example 1 is repeated, except that the kind and dosage of the raw materials were changed. The formulation and evaluation results were shown in Table 3.

### Evaluation Method

### Molecular Weight Distribution of Novolac Resin (A)

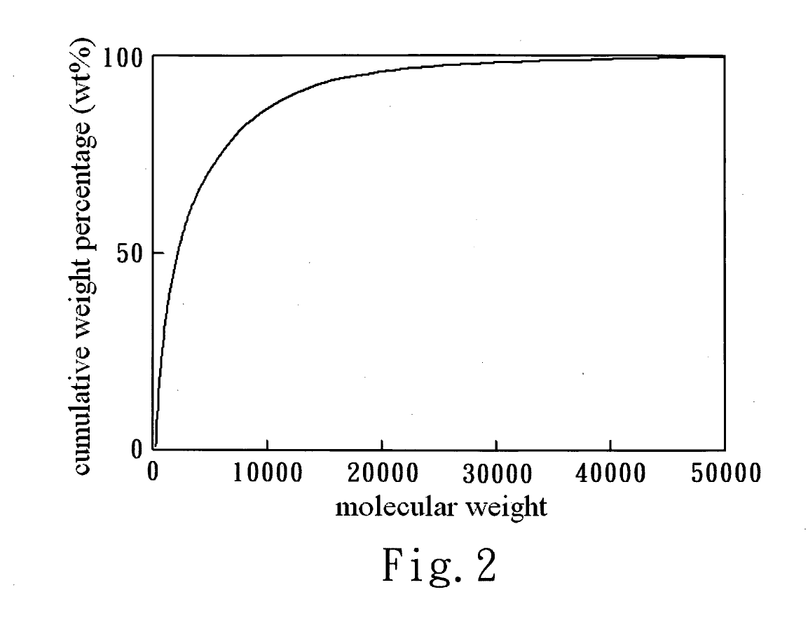

In the present invention, the molecular weight distribution of novolac resin (A) was determined by Gel permeation chromatography (GPC) according to the following measurement conditions. In the scope of GPC determination, after integrating the intensity of the resin between 200 and 120,000, an integral molecular weight distribution curve was obtained by plotting the molecular weight on the horizontal axis versus the cumulative weight percentage on the vertical axis as shown in FIG. 2. The weight percentage of novolac resin with molecular weight of from 1,000 to 3,000 and molecular weight of more than 30,000 in the novolac resin (A) were respectively calculated.

### GPC Measurement Conditions

Device: 717 plus (manufactured by Waters)

Column: 79911 GP-501, 79911 GP-502, 79911 GP-503, 79911 GP-504 (manufactured by Agilent Technologies)

Detector: 2414 RI Detector (manufactured by Waters)

Mobile phase: Tetrahydrofuran

Flow rate: 1.0 mL/min

Injection volume: 100 μL

Measurement temperature: 40° C.

Measurement time: 60 minutes

Molecular weight standard: Polystyrene

### Coating Uniformity

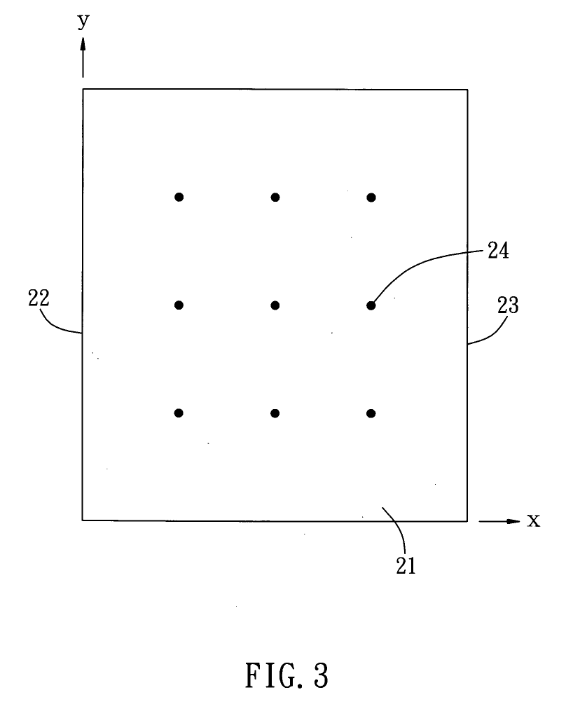

The photosensitive resin composition was coated on a 1100 mm×960 mm glass substrate by the slit coating process, and then pre-baked at a temperature of 110° C. for a time period of 90 seconds to form a pre-baked coating film. Thereafter, the pre-baked coating film was measured with Tencor α-step probe to determine the thickness of the film. Measurement points are shown in FIG. 3. The lengths of the glass substrate (21) along the x axis direction and the y axis direction are 960 nm and 1100 nm, respectively. Let the side of the substrate (21) at x=0 be the start (22) and let the opposite side relative to the start (22) of the substrate (21) be the end (23), the direction of slit coating of the positive photosensitive resin composition is from the start (22) towards the end (23) paralleled to the x-axis.

FT(avg) is an average thickness of nine thicknesses obtained on the measurement points (64) as follows: (x,y)=(240,75), (480,275), (720,275), (240,550), (480,550), (720,550), (240,825), (480,825), (720,825).

FT(x,y)ₘₐₓ is the maximum of the nine thicknesses obtained on the aforementioned measurement points (64).

FT(x,y)ₘᵢₙ is the minimum of the nine thicknesses obtained on the aforementioned measurement points (64).

The coating uniformity can be determined according to the following equation:

$$Coating uniformity ( U ) = \frac{{FT ( x , y )}_{max} - {FT ( x , y )}_{min}}{2 \times FT ( avg )} \times 100 \%$$

◯: below 3%

Δ: between 3% and 5%

X: above 5%

### Developing Properties

The pre-baked coating film obtained from the evaluation of coating uniformity was irradiated with UV (AG500-4N, manufactured by M&R Nano Technology) in 10 mJ/cm² through a pattern mask. After developed in a developing solution (2.38% tetramethylammonium hydroxide) at a temperature of 23° C. for a time period of 1 minute, the exposed regions of the coating film on the substrate were removed. Thereafter, washing with pure water and post-baking at a temperature of 140° C. for a time period of 20 minutes were performed to obtain a required pattern on the glass substrate. The substrate was observed by a microscope to inspect scum.

◯: no scum

X: obvious scum

### Sensitivity

A transmission step wedge (T2115, manufactured by Stouffer Industries, 21 steps in optical density increments) was attached on the pre-baked coating film obtained from the evaluation of coating uniformity, and then irradiated with UV (AG500-4N, manufactured by M&R Nano Technology) in 100 mJ/cm². After developed in a developing solution (2.38% tetramethylammonium hydroxide) at a temperature of 23° C. for a time period of 1 minute, following by washing with pure water, the sensitivity was inspected according to the steps of measurements (higher steps indicating higher sensitivities).

◯: step 9˜21

Δ: step 7˜8

X: step 1˜6

### Film Residual Ratio

After the film thickness (δ) of any measurement point on the pre-baked coating film obtained in the evaluation of coating uniformity was measured, following by developing in a developing solution (2.38% tetramethylammonium hydroxide) at a temperature of 23° C. for a time period of 1 minute, another film thickness (δ_{d}) was measured at the same measurement point. The film residual ratio can be determined according to the following equation:

Film residual ratio (%)=[(δ_{d})/(δ)]×100

◯: above 90%

Δ: between 80% and 90%

X: below 80%

While the present invention is illustrated with the preferred embodiments aforementioned, scope of the invention is not thus limited and should be determined in accordance with the appended claims.

TABLE 1

| | Composition (mole) | | | | | | | | |
|---|---|---|---|---|---|---|---|---|---|
| | | | | | | | Acid | Reaction | |
| Synthesis | Aromatic Hydroxy Compound | | | | | Aldehyde | Catalyst | Temp. | Condensation |
| Example | o-cresol | m-cresol | p-cresol | 2,5-xylenol | 2,3,5-trimethylphenol | formaldehyde | oxalic acid | (° C.) | Time (hr) |
| A-1 | | 0.60 | 0.40 | | | 0.60 | 0.020 | 100 | 5 |
| A-2 | 0.05 | 0.65 | 0.35 | | | 0.68 | 0.015 | 100 | 5 |
| A-3 | | 0.70 | 0.30 | 0.05 | | 0.72 | 0.015 | 105 | 5 |
| A-4 | | 0.80 | 0.20 | | 0.02 | 0.76 | 0.020 | 105 | 5 |

| | |
|---|---|
| English Name | Molecular Weight |
| o-cresol | 108.14 g/mol |
| m-cresol | 108.15 g/mol |
| p-cresol | 108.16 g/mol |
| 2,5-xylenol | 122.17 g/mol |
| 2,3,5-trimethylphenol | 136.19 g/mol |
| formaldehyde | 30.03 g/mol |
| oxalic acid | 90.03 g/mol |

TABLE 2

| | Weight Percentage of Novalac Resin with Specific | |
|---|---|---|
| | Molecular Weight in the Novalac Resin (A) (% by weight) | |
| Synthesis | Molecular Weight of | Molecular Weight of |
| Example | From 1,000 to 3,000 | More Than 30,000 |
| A-1 | 4 | 12 |
| A-2 | 3 | 15 |
| A-3 | 3 | 17 |
| A-4 | 2 | 18 |
| A-5 | 2 | 21 |
| A-6 | 10 | 6 |
| A-7 | 24 | 4 |
| A-8 | 33 | 2 |
| A-9 | 40 | 1 |
| A-10 | 47 | 0.3 |

TABLE 3

| | | | Example | | | | | | | Comparative Example | | | | | | |
|---|---|---|---|---|---|---|---|---|---|---|---|---|---|---|---|---|
| Component | | | 1 | 2 | 3 | 4 | 5 | 6 | 7 | 1 | 2 | 3 | 4 | 5 | 6 | 7 |
| Novolac Resin (A) | | A-1 | | | | | 70 | | | 100 | | | | | | |
| (parts by weight) | | A-2 | | | | | | | | | 100 | | | | | |
| | | A-3 | | | | | | | 5 | | | 100 | | | | |
| | | A-4 | | | | | | 40 | | | | | 100 | | | 80 |
| | | A-5 | | | | | | | | | | | | 100 | | |
| | | A-6 | 100 | | | | 30 | | | | | | | | | |
| | | A-7 | | 100 | | | | 60 | | | | | | | | |
| | | A-8 | | | 100 | | | | | | | | | | | |
| | | A-9 | | | | 100 | | | | | | | | | | 20 |
| | | A-10 | | | | | | | 95 | | | | | | 100 | |
| O-Naphthoquinone Diazide | | B-1 | 25 | 35 | 25 | 25 | | 25 | 25 | 25 | 25 | 25 | 25 | 25 | 25 | 25 |
| Sulfonic Acid Ester (B) | | B-2 | 10 | | 10 | 10 | 35 | 10 | 10 | 10 | 10 | 10 | 10 | 10 | 10 | 10 |
| (parts by weight) | | | | | | | | | | | | | | | | |
| Solvent (C) | | C-1 | 1200 | 1200 | 1000 | 1200 | 1200 | 1200 | | 1200 | 1200 | 1200 | 1200 | 1200 | 1200 | 1200 |
| (parts by weight) | | C-2 | | | 200 | | | | 1200 | | | | | | | |
| Additive (D) | | D-1 | | | | | 0.2 | | | | | | | | | |
| (parts by weight) | | D-2 | | 3 | | | 3 | | | | | | | | | |
| Evalution | *Molecular | 1,000~3,000 | 10 | 24 | 33 | 40 | 5 | 15 | 45 | 4 | 3 | 3 | 2 | 2 | 47 | 10 |
| Method | Weight | more than | 6 | 4 | 2 | 1 | 9 | 10 | 1 | 12 | 15 | 17 | 18 | 21 | 0.3 | 15 |
| | Distribution | 30,000 | | | | | | | | | | | | | | |
| | (% by weight) | | | | | | | | | | | | | | | |

| | | | | | | | | | | | | | | |
|---|---|---|---|---|---|---|---|---|---|---|---|---|---|---|
| Coating Uniformity | ◯ | ◯ | ◯ | ◯ | ◯ | ◯ | ◯ | X | X | X | X | X | ◯ | X |
| Developing Properties | ◯ | ◯ | ◯ | ◯ | ◯ | ◯ | ◯ | X | X | X | X | X | ◯ | X |
| Sensitivity | ◯ | ◯ | ◯ | ◯ | ◯ | ◯ | ◯ | X | X | X | X | X | ◯ | X |
| Film Residual Ratio | ◯ | ◯ | ◯ | Δ | ◯ | ◯ | Δ | ◯ | ◯ | ◯ | ◯ | ◯ | X | ◯ |

B-1 ester of 2,3,4-trihydroxy benzophenone and 1,2-naphthaquinone diazide-5-sulfonic acid
B-2 ester of 2,3,4,4′-tetrahydroxy benzophenone and 1,2-naphthaquinone diazide-5-sulfonic acid
C-1 PGMEA, propylene glycol monomethyl ether acetate
C-2 EL, ethyl lactate
D-1 Surfactant: SH29PA (trade name, manufactured by Toray Dow Corning Silicone)
D-2 Adhesion Auxiliary Agent: Cymel-300(trade name, manufactured by Mitsui Chemicals)
*Moleclar Weight Distribution: the weight percentage of novolac resin with molecular weight of from 1,000 to 3,000 and molecular weight of more than 30,000 in the novolac resin(A) respectively.

What is claimed is:

1. A positive photosensitive resin composition for slit coating process comprising:
a novolac resin (A);
an o-naphthaquinone diazide sulfonic acid ester (B); and
a solvent (C);
wherein the novolac resin (A) has a cumulative weight percentage of from 5% to 45% with molecular weight of from 1,000 to 3,000 and the novolac resin (A) also has a cumulative weight percentage of less than 10% with molecular weight of more than 30,000, both of which can be calculated by integral molecular weight distribution curve obtained by plotting the cumulative weight percentage versus molecular weight falling within a range between 200 and 120,000 determined by gel permeation chromatography.

2. A method for forming a pattern using the positive photosensitive resin composition as claimed in claim 1, comprising the following steps: coating on a substrate, pre-baking, exposure, developing and post-baking.

3. A thin-film transistor array substrate including a pattern as claimed in claim 2.

4. A liquid crystal display element including a thin film transistor array substrate as claimed in claim 3.
